(19) United States
(12) Patent Application Publication
(10) Pub. No.: US 2015/0109015 A1
(43) Pub. Date: Apr. 23, 2015

(54) SYSTEM-LEVEL TESTING OF NON-SINGULATED INTEGRATED CIRCUIT DIE ON A WAFER

(71) Applicants: ATI Technologies ULC, Markham (CA); Advanced Micro Devices, Inc., Sunnyvale, CA (US)

(72) Inventors: Trent W. Johnson, Chicago, IL (US); Ray Steiger, North Gower (CA); Jian Wei, Markham (CA); Anatoly Fridman, Newmarket (CA)

(21) Appl. No.: 14/060,261

(22) Filed: Oct. 22, 2013

(51) Int. Cl. G01R 1/04; G01R 1/073

(52) U.S. Cl. CPC G01R 1/0433; G01R 1/073
USPC 324/756.03

(57) ABSTRACT

Structures and methods for system-level testing of integrated circuit dies at wafer sort is disclosed. This concept combines a system-level test (which is traditionally a “socketed” test performed on a packaged IC in a test socket) with the ability to contact an integrated circuit die on a wafer using a probe card. The die on the wafer becomes part of the system-level environment in order to test the integrated circuit die in the system-level environment prior to packaging, and may be used to better identify known good die.

### BACKGROUND

1. Field of the Disclosure

This application relates to testing integrated circuit dies on a wafer, and more particularly relates to testing such integrated circuit dies in a system-level environment.

2. Description of the Related Art

Integrated circuit dies are almost always tested while still part of the processed semiconductor wafer (i.e., “non-singulated” dies). Such testing is frequently termed “wafer sort” and is frequently optimized to determine, in as short a test time as possible, which integrated circuit dies are functional at nominal operating conditions and thus are worthy of the additional cost of packaging. Later, the packaged integrated circuits (ICs) are more rigorously tested at what is frequently called “final test” to determine which ICs operate properly over the specified voltage, frequency, and environmental range. If an IC passes at wafer sort, but fails at final test, that IC must be discarded, along with the attendant cost of its packaging and final test operation.

More recently, integrated circuits are sometime packaged together with other integrated circuits. For example, in 2.5D or 3D packaging techniques, two or more dies may be bonded together and interconnected, such as using through-silicon-vias (TSV's), then packaged together in a single protective package. If traditional wafer sort/final test techniques are applied to such a multiple integrated circuit packaged device, a single die which passes at wafer sort, but fails at final test, now results in several discarded dies, the others of which were likely fully functional, and also results in a discarded package that is likely much more expensive than a single-die package.

Such high-density multiple-die packaging techniques place a significant importance on determining “known good dies” (KGD's) at wafer sort testing, so that only such KGD's are packaged together with other KGD's.

### SUMMARY OF EMBODIMENTS

System-level testing of integrated circuit dies at wafer sort may be used to better identify known good die. Such testing combines a system-level test (which is traditionally a “socketed” test performed on a packaged IC in a test socket) with the ability to contact an integrated circuit die on a wafer using a probe card. The die on the wafer becomes part of the system-level environment in order to test the integrated circuit die in the system-level environment prior to packaging.

One aspect provides a method for testing integrated circuit die on a semiconductor wafer. In an exemplary embodiment, the method includes initializing a module comprising circuitry employed in a system-level circuit environment, to provide an operable system-level environment when coupled to an integrated circuit that is not present on the module. The method also includes contacting a plurality of probe needles to a respective plurality of electrical connection points of a first integrated circuit die on a semiconductor wafer. The plurality of probe needles are electrically coupled to respective connections on the module. The method then continues with initializing the first integrated circuit die to provide, together with the initialized module, the operable system-level environment, and then performing a system-level test of the first integrated circuit die in the operable system-level environment.

In some embodiments, the aforementioned performing a system-level test includes operating the first integrated circuit die in the system-level environment under at least one set of operating conditions, and registering success or failure of the first integrated circuit die during such operation.

In some embodiments, the method also includes decoupling the plurality of probe needles from the respective plurality of electrical connection points of the first integrated circuit die, while maintaining the initialization of the module, then contacting the plurality of probe needles to a respective plurality of electrical connection points of a second integrated circuit die on the semiconductor wafer, then initializing the second integrated circuit die to provide, together with the initialized module, the operable system-level environment, and then performing a system-level test of the second integrated circuit die in the operable system-level environment.

In some embodiments, the probe needles are part of a probe-load board for a wafer prober, and the module is implemented, at least in part, external to the probe-load board, and is connected to the probe-load board by a cable. The module may be partially implemented on the probe-load board. In some embodiments, the probe needles are part of a probe-load board for a wafer prober, and the module is implemented on the probe-load board. In some embodiments, the probe needles are part of a probe-load board for a wafer prober, and the module is implemented, at least in part, within an automated test equipment (ATE) test head that is operably connected to the probe-load board.

In some embodiments, the module may be a motherboard implementation including an associated processor device, the initializing the module may include booting an operating system on the motherboard implementation, and the first integrated circuit die may include a graphics processing unit (GPU). In some embodiments, the module may be a motherboard implementation without an associated processor device, and the first integrated circuit die may be a processor device operable with the motherboard implementation.

In some embodiments, the first integrated circuit die may be a processor device. In some of these embodiments, the processor device may include at least one of a graphics processing unit (GPU), a central processing unit (CPU), and an accelerated processing unit (APU).

Another aspect provides a test apparatus for testing an integrated circuit die on a semiconductor wafer. In an exemplary embodiment, the apparatus includes a module that includes circuitry employed in a system-level circuit environment. The module is operable to provide an operable system-level environment when initialized and coupled to an integrated circuit that is not present on the module. The apparatus also includes a probe-load board operable with a wafer prober. The probe-load board includes a plurality of probe needles operable to contact a respective plurality of electrical connection points of a first integrated circuit die on a semiconductor wafer. The plurality of probe needles are electrically coupled to respective connections on the module. The apparatus also includes a test controller operable to initialize the module and initialize the first integrated circuit die to provide, together with the initialized module, the operable system-level environment, and further operable to initiate and monitor a system-level test of the first integrated circuit die in the operable system-level environment.

In some embodiments, the system-level test includes operation of the first integrated circuit die in the system-level environment under at least one set of operating conditions, and registration of success or failure of the first integrated circuit die during such operation.

In some embodiments, the test controller is further operable to cause the wafer prober to decouple the plurality of probe needles from the respective plurality of electrical connection points of the first integrated circuit die, while maintaining the initialization of the module, then cause the wafer prober to contact the plurality of probe needles to a respective plurality of electrical connection points of a second integrated circuit die on the semiconductor wafer, then initialize the second integrated circuit die to provide, together with the initialized module, the operable system-level environment, and then initiate and monitor a system-level test of the second integrated circuit die in the operable system-level environment.

In some embodiments, the module is implemented, at least in part, external to the probe-load board, and is connected to the probe-load board by a cable. The module may be partially implemented on the probe-load board. In some embodiments, the module is implemented on the probe-load board. In some embodiments, the module is implemented, at least in part, within an automated test equipment (ATE) test head that is operably connected to the probe-load board.

In some embodiments, the module may be a motherboard implementation including an associated processor device, and the module may be initialized by booting an operating system on the motherboard implementation.

In some embodiments, the first integrated circuit die may be a processor device that includes at least one of a graphics processing unit (GPU), a central processing unit (CPU), and an accelerated processing unit (APU).

The foregoing is a summary and thus contains, by necessity, simplifications, generalizations and omissions of detail. Consequently, those skilled in the art will appreciate that the foregoing summary of embodiments is illustrative only and is not intended to be in any way limiting of the invention. It is only the claims, including all equivalents, in this or any application claiming priority to this application, that are intended to define the invention.

### BRIEF DESCRIPTION OF THE DRAWINGS

The present disclosure may be better understood by referencing the accompanying drawings.

FIG. 1 is a block diagram of a test apparatus for system-level testing of an integrated circuit die on a wafer, according to some embodiments.

FIG. 2 is a cross-section diagram of a load board structure, a wafer chuck of a prober, and external electrical connections, according to some embodiments.

FIG. 3 is a cross-section diagram of a load board structure with a bridge beam, a wafer chuck of a prober, and electrical connections to an external motherboard, according to some embodiments.

FIG. 4 is a perspective view of a test apparatus including a load board, a bridge beam, a load board stiffener, and electrical connections to an external motherboard, according to some embodiments.

FIG. 5 is a cross-section diagram of a test head operable with a wafer prober, according to some embodiments.

FIG. 6 is a further cross-section diagram of the test head shown in FIG. 5, according to some embodiments.

FIG. 7 is a further cross-section diagram of the test head shown in FIG. 5, according to some embodiments.

The use of the same reference symbols in different drawings indicates similar or identical items.

### DETAILED DESCRIPTION

System-level testing of integrated circuit dies at wafer sort conceptually combines a system-level test (which is traditionally a “socketed” test performed on a packaged IC in a test socket) with the ability to contact an integrated circuit die on a wafer using a probe card. The die on the wafer becomes part of the system-level environment in order to test the integrated circuit die in a system-level environment prior to packaging.

Various embodiments are disclosed in which a module is coupled to an integrated circuit to be tested (i.e., the “device under test” or DUT). Together, the module and the DUT provide a system-level environment, and the DUT is tested while operating in such a system-level environment.

System-level testing inherently offers the highest possible amount of functional test coverage. Performing this type of testing at wafer sort provides several advantages: it increases functional test coverage at wafer probe/sort; it allows high test coverage at wafer probe/sort without the design and simulation work required for traditional ATE test; it mitigates situations where design-for-test (DFT) features are broken or ineffective; and it provides a suitable test methodology for test scenarios that have inherent “non-determinism.” Moreover, it is applicable to any active component that is intended to be installed in a “system” to form a product, but is particularly effective for testing large VLSI devices such as central processing units (CPUs), graphics processing units (GPUs), accelerated processing units (APUs), chipset devices, or other devices such as mobile phone application specific integrated circuits (ASICs) and embedded processors. An APU integrates a CPU and a GPU on the same integrated circuit die.

The described system-level testing techniques may be used to provide high test coverage at wafer sort and thus better identify known good die without relying on strict design for test (DFT) considerations in the design of the integrated circuit, and without relying on extensive ATE pattern engineering at wafer sort. Since such ATE efforts are sometimes not available during early production runs, the described techniques can significantly improve die-to-ship yields, particularly during the first few months of early production runs of a new silicon design. It also reduces dependence upon skilled ATE pattern engineering personnel to devise test coverage routines, yet still achieve high test quality without relying on ATE functional test at wafer sort, nor any special DFT test at wafer sort, which both require significant up-front design and simulation work. If the desired test coverage is not provided early using these two methodologies, there may be a significant lag in adding such coverage later. For some kinds of multiple-die products, the described techniques may reduce die-to-ship failure fallout by as much as 65-80% and may significantly reduce the per-unit product cost during the initial silicon samples phase.

In certain example embodiments, this may be accomplished by putting enough system components on an ATE probe card to allow system-level testing using wafer die as the device under test. In other words, the entire system may be implemented on the probe card (and/or load board). In some embodiments, the system may be partially implemented on the probe card and/or load board, and partially implemented in a module that is connected to the probe card or load board using a cable (e.g., a “dongle cable” or other type of multi-conductor “umbilical” cable). In some embodiments, the system may be partially or entirely implemented in an ATE instrument form factor to be easily contained in a standard ATE test head, and use a standard probe card.

In certain example embodiments, a test apparatus for a GPU die includes a probe card on which is implemented a graphics board, and a cable to connect the probe card to a computer motherboard to provide an operable system-level environment for testing the GPU die. In certain example embodiments, a test apparatus for a CPU die includes a probe card on which is implemented a computer motherboard that includes a system chipset, to provide an operable system-level environment for testing the CPU die.

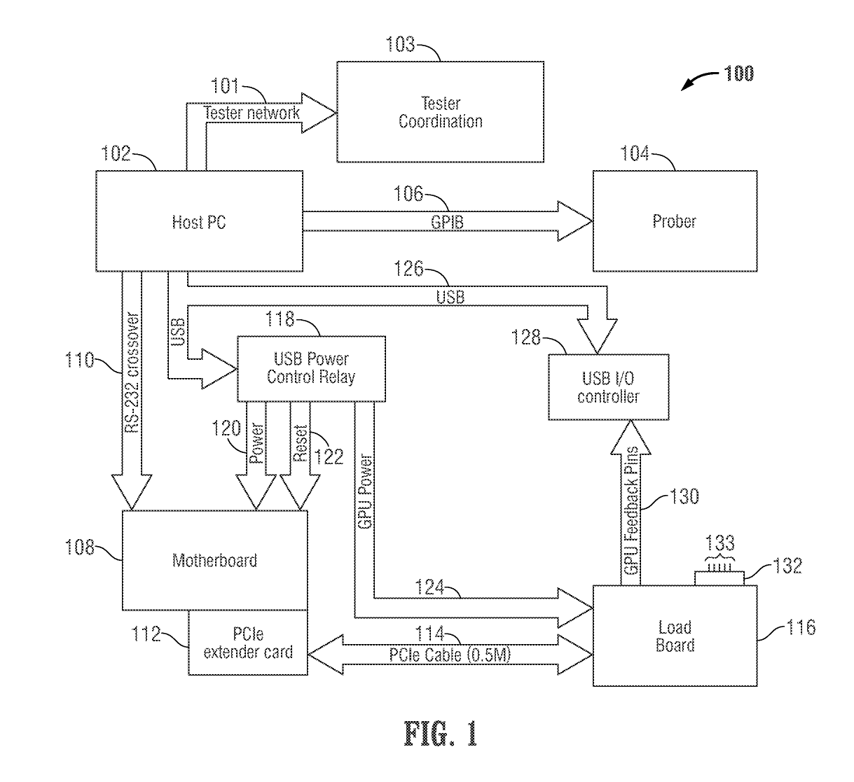

Referring now to FIG. 1, a block diagram is shown of one such test apparatus 100, which includes a controller 102 for the test apparatus 100. In this example, the controller 102 is a Host PC, although other kinds of computers and devices may also be used to initiate and control the test sequences for test apparatus 100. The controller 102 optionally communicates with a tester coordination infrastructure 103 over a tester network 101, as would typically be the case in a manufacturing environment having multiple test equipment devices.

The controller 102 controls a wafer prober 104 over bus 106, which in this example is a GPIB bus (i.e., IEEE 488 bus). An exemplary prober 104 is the TEL P12 prober available from Tokyo Electron, although many other models and brands of probers may also be used. The controller 102 also controls a motherboard 108 by way of a bus 110, which in this example is a serial communication bus using a RS-232 cross-over cable. The controller 102 also controls a power control relay 118 and I/O controller 128 by way of bus 126, which in this example is a USB bus.

The motherboard 108 includes a PCIe extender card 112 coupled to a load board 116 by a PCIe extender cable 114. A probe card 132 attached to the load board interfaces with the prober 104. The power control relay 118 provides power signals 120 and control signals 122 (e.g., a RESET signal) to the motherboard 108 in response to control inputs received from the controller 102, and also provides power signals 124 to the load board 116 for powering the GPU device being tested. The load board 116 also communicates signals from the GPU being tested to the I/O controller 128 by way of bus 130, which GPU signals are communicated to the controller 102 by way of, for example, the USB bus 126.

The motherboard 108, the PCIe extender card 112, the PCIe extender cable 114, and the load board 116 together may be viewed as a module that includes circuitry employed in a system-level circuit environment, to provide an operable system-level environment when coupled to an integrated circuit that is not present on the module. In this example, the module provides a fully-functional personal computer system when coupled to a GPU device to be tested, which is not part of the module.

The above exemplary test apparatus 100 is described in the context of specific devices, busses and/or cables, but other kinds of devices, control busses and/or cables may also be used. It should also be understood that the diagram depicted in FIG. 1 is a functional block diagram that is not meant to infer that each such block is necessarily an identifiably separate block. For example, the motherboard 108 functionality may be implemented entirely on the load board 116, so that the PCIe extender cable 114 is not used. Such a configuration may be particularly useful, for example, for testing CPU devices because the wire lengths between the CPU under test and motherboard's system chipset devices on the load board 116 may be kept relatively short and lightly loaded. As another example, the power control relay block 118 may be implemented on the motherboard 108, or may be implemented on the load board 116, especially if the motherboard 108 is also implemented on the load board 116.

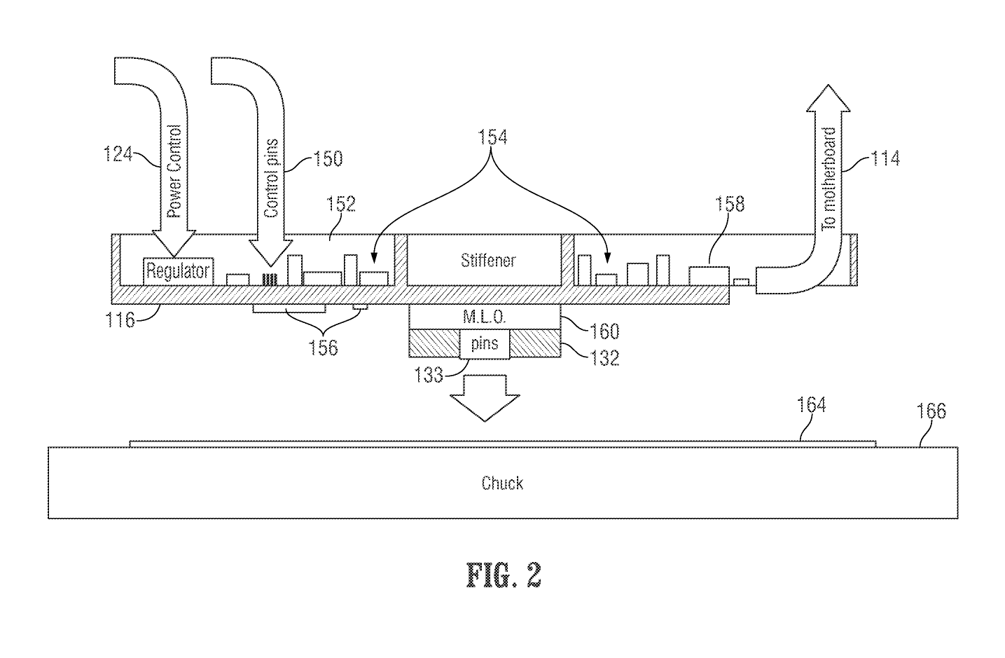

Referring now to FIG. 2, an exemplary load board 116 is securely mounted to a stiffener 152 to reduce deflections during probe operation, and especially when the probe needles are in contact with the wafer. Various components 154 are shown attached to the top side of the load board 116, and additional components 156 are shown attached to the bottom side of the load board 116. In the example being described, the components 154, 156 implement a PCIe-compatible graphics card that is operable with the motherboard 108, and also operable with the GPU to be tested. Because of clearance issues, the bottom components 156 may include decoupling capacitors because of their proximity to the probe card 132, and also may include buffer memory for interfacing to the GPU to be tested. In a broader sense, these components 154, 156 may partially or fully implement the module which, together with the device to be tested, provides the operable system-level environment.

The load board 116 receives power by way of a power control bus 124 conveyed, for example, from the power control relay 118, and also receives control signals 150 from the power control relay 118 and/or the motherboard 108. Conversely, the load board 116 is also coupled to the motherboard 108 by way of bus 114, which in this example corresponds to a PCIe extension cable which connects to PCIe extension connector 158. For performance reasons, the PCIe extension cable 114 is preferably no longer than 1 meter in length.

A probe card 132 (also referred to as “probe head” 132) is coupled to the load board 116 using, for example, a multi-layer organic substrate 160 (i.e., MLO 160) to provide high performance signal integrity. In other embodiments, a multi-layer ceramic (MLC) substrate may be used in place of MLO 160. Similarly, other structures and techniques may also be used to couple the probe card 132 to the load board 116. The probe needles 133, also referred to as probe pins 133, are mounted on the bottom surface of the probe card 132, and are used to contact respective connection points on the integrated circuit die on the wafer which is to be tested. Such a wafer 164 is shown atop a probe chuck 166 of the prober 104.

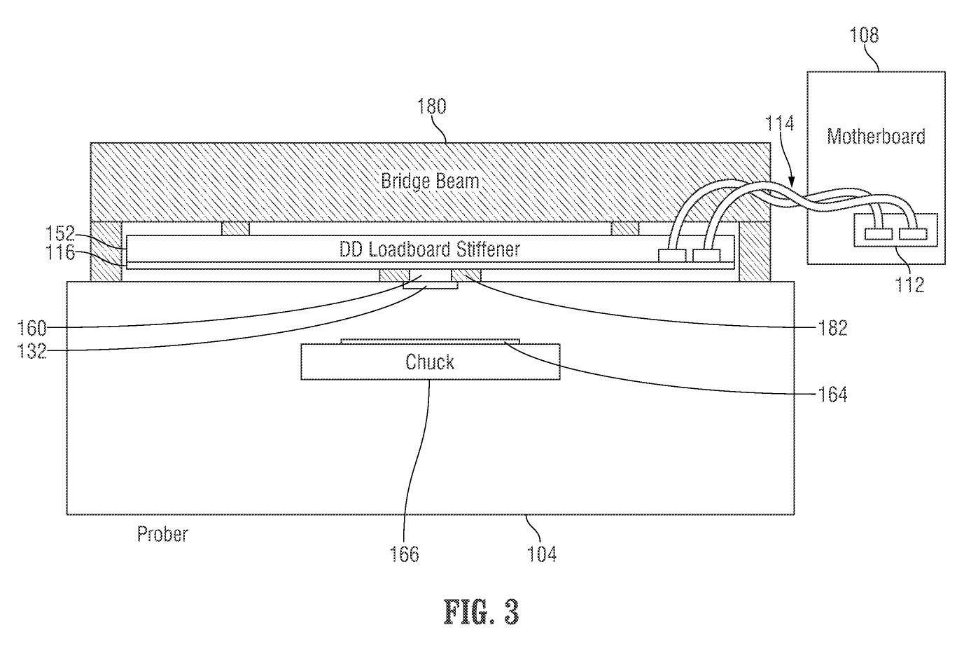

FIG. 3 depicts an arrangement in which a bridge beam 180 is used to further support a load board 116 and probe card 132. Such a bridge beam may traverse over and across only a middle stripe of the load board 116, including the area in the center of the load board 116 to which the probe card 132 is attached, while leaving exposed the side regions of the load board 116 for better access to components and cable connections. In such a case, FIG. 3 represents a side view of such a bridge beam 180. In contrast, the direct dock load board stiffener 152 may extend more fully to the edges of the load board 116, but include a series of cutouts machined between orthogonal sets of lateral beams to provide access to components and cable connections. Also shown is mounting hardware 182 for coupling the probe card 132 and the MLO 160 to the load board 116. In certain embodiments, an interposer (not shown) that includes a pogo-style pin array may be used to couple the MLO 160 to the load board 116, and the mounting hardware 182 may take the form of a collar or containment case that holds the various pieces together. The bridge beam 180 together with the stiffener 152 help provide mechanical stability and a good mechanical “fit” to the prober 104.

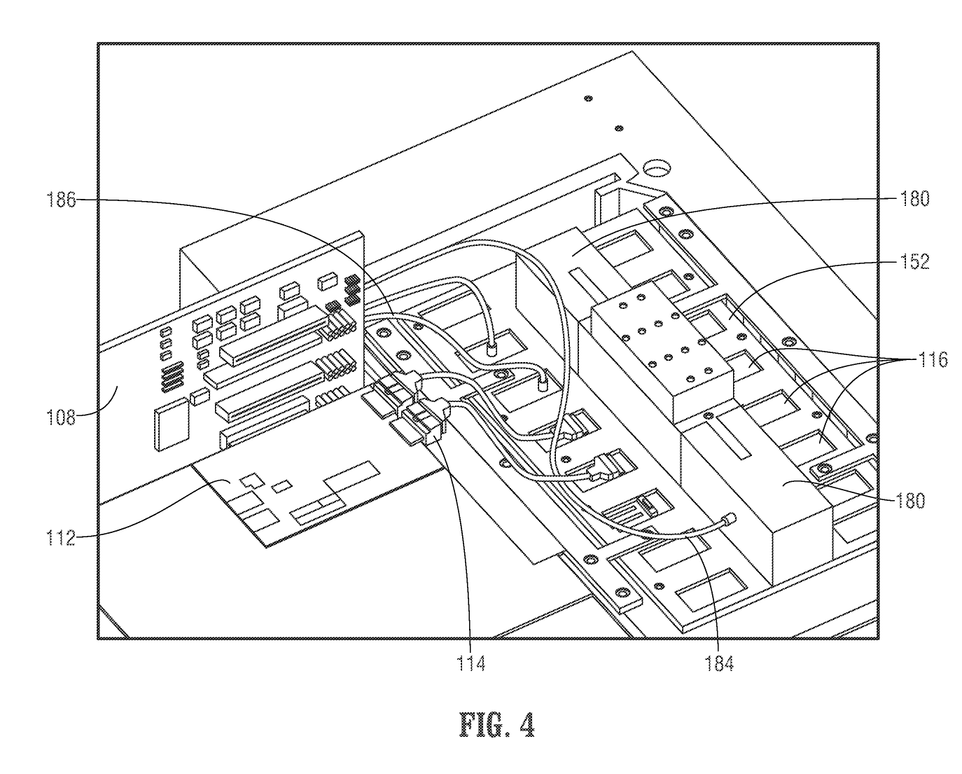

FIG. 4 is a perspective view of an exemplary test apparatus showing a direct-dock (DD) load board 116 visible though the cutouts of the stiffener 152, a bridge beam 180 traversing across a middle portion of the stiffener 152 and load board 116 combination, a pair of PCIe extender cables 114 connecting the load board 116 to an adapter card 112, which is connected to a PCIe slot on a motherboard 108. In this example, the PCIe extender cables are 2-8 lane XGP cables, which mate to 2 by 8 JAE connectors on both the adapter card 112 and the load board 116. Cables 184, 186 couple the load board 116 to power control relays (not shown) and a Host PC or other controller (not shown) used to supervise the test apparatus.

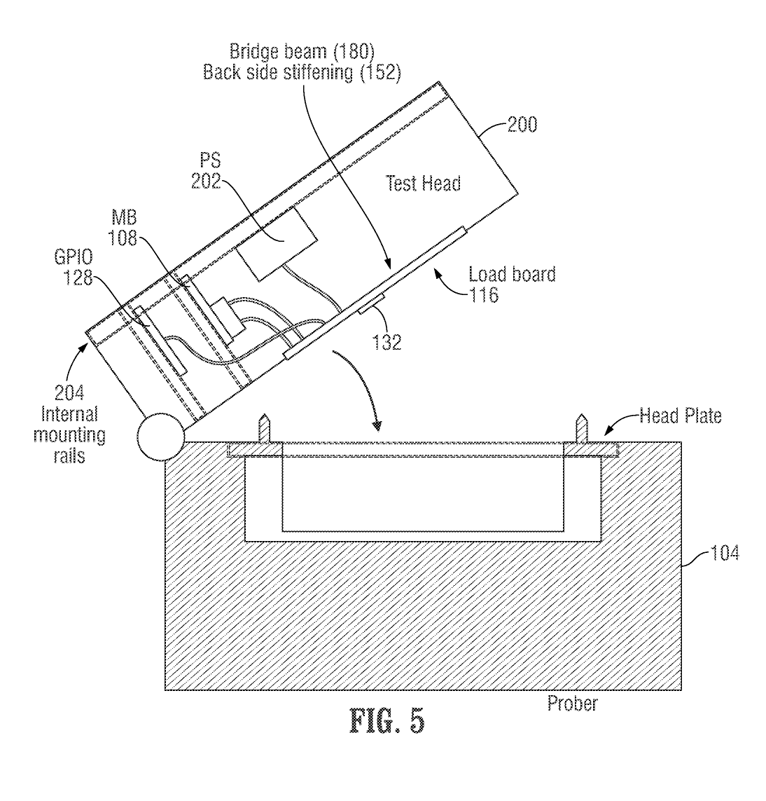

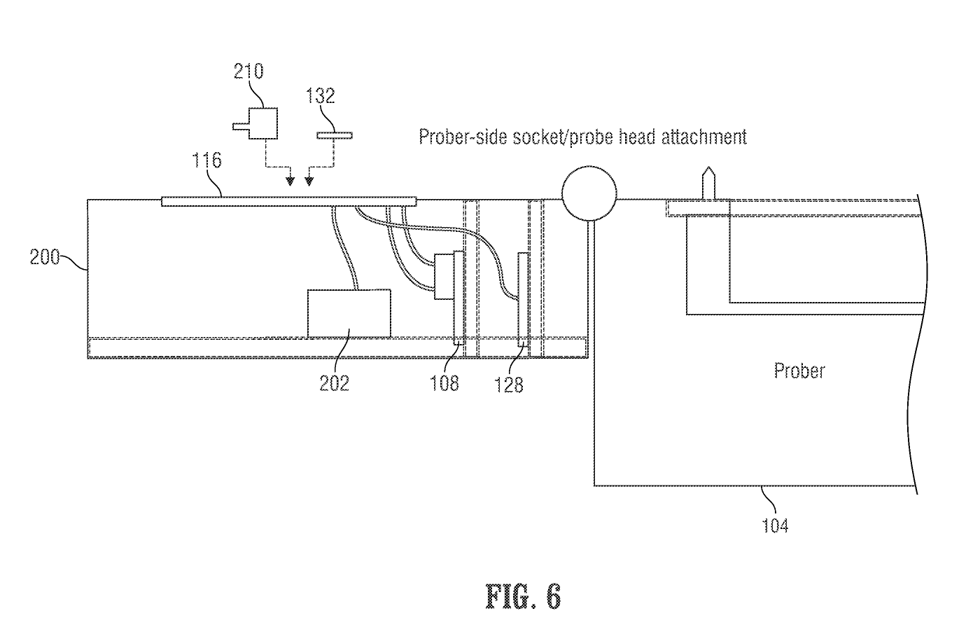

Referring now to FIG. 5, a test head 200 is depicted which incorporates the load board 116 (including probe card 132 and bridge beam 180/back side stiffener 152), and also incorporates the motherboard 108, power supply 202, and GPIO 128, each mounted to internal mounting rails 204. Such an arrangement can result in shorter connection lengths for the high frequency signal interconnections, particularly between the motherboard 108 and load board 116, and thus better provide a system-level environment with less signal deterioration and other negative effects due to long interconnect cables. The test head 200 disengages from the prober 104 and hinges to one side to provide access to the prober 104, including the wafer chuck 166 (not shown in FIG. 5), and may be hinged by 180 degrees to achieve a horizontal position aside the prober 104 with the load board 116 facing up. This position, shown in FIG. 6, affords excellent access to the load board 116, and allows easy insertion and removal of a probe card 132, or alternatively a socket 210 for testing a packaged device, which is useful for test correlation or other “golden unit” testing.

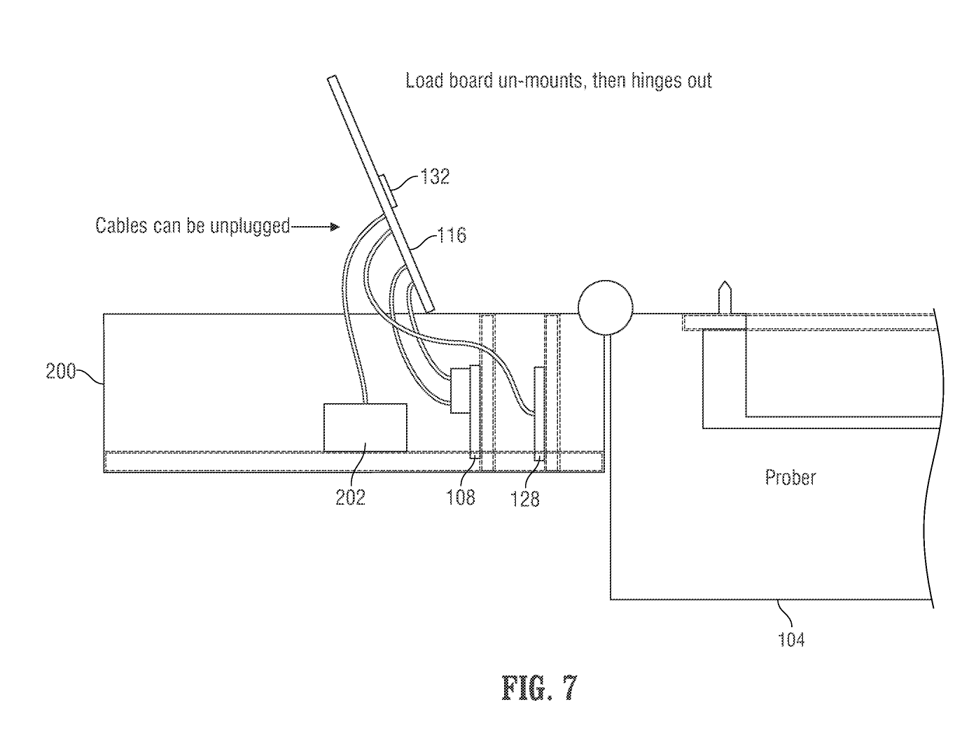

FIG. 7 also shows the test head 200 in the fully hinged-open (disengaged) position, and illustrates how the load board 116 may also be hinged to provide access to the modules, boards, connectors, cables, and other internal components within the test head. The side panels of the test head 200 may also be configured for easy removal, to afford access to the internal components without having to unhinge the load board 116. When the test head 200 is engaged with the prober 104, as indicated by the arrow in FIG. 5, these same side panels may be removed to afford access to the internal components of the test head 200.

As mentioned above, such a system-level test at wafer sort may be used with “first silicon” if more comprehensive pattern-based test routines are not yet developed, and may also be used to aid in wafer-level characterization at any time during the product lifetime. While system-level test times to achieve satisfactory test coverage may be somewhat more lengthy than test times for more traditional ATE-based test capabilities, the incremental cost of replicating additional system-level environment test stations may be low enough to provide equivalent aggregate throughput and test capacity. As with any robust test equipment, a production-worthy system-level test at wafer sort capability should preferably attend to providing the test equipment in a neat enclosure, reducing the number of cables to one or but a few robust cables or cable snakes, and protecting the prober docking area with a cover to reduce particle debris.

Pin continuity may be provided by checking pin continuity at each of the four corners and at the center of the die, then overdriving the chuck by a few microns to ensure full continuity of all pins. Checking each of these five pins may be accomplished using a second corresponding pin that is connected to the same signal, such as a pair of power pins.

Proper cooling during the system-level test may be important, depending upon the power dissipation of the DUT during the system-level test. Many commercial probers provide an option for active chuck cooling that is likely adequate for testing.

In an exemplary test methodology, a module is provided that includes circuitry employed in a system-level circuit environment. The controller 102 initializes the module to provide an operable system-level environment when coupled to an integrated circuit that is not present on the module. The controller 102 also causes the prober 104 to contact a plurality of probe needles to a respective plurality of electrical connection points of an integrated circuit die on a semiconductor wafer. The plurality of probe needles are electrically coupled to respective connections on the module, either directly through on-board connections, or indirectly through drivers, amplifiers, and load structures. The module may be implemented at least partially on a probe card, load board, or a combination probe-load board, and implemented partially external to the load board and connected to the load board by a cable.

The first integrated circuit die is initialized to provide, together with the initialized module, the operable system-level environment. Such initializing the integrated circuit may be as simple as merely delivering power to the integrated circuit, but also may include loading registers, loading configuration parameters, and/or providing time for a power-up boot sequence or self-test operation of the integrated circuit device.

In certain exemplary embodiments, the controller 102 then initiates and monitors a system-level test of the integrated circuit die in the operable system-level environment under at least one set of operating conditions (e.g., voltage, temperature, timing, etc.) and logs (i.e., “registers”) the success or failure of such test, then causes to the prober to index to a new die, while maintaining the initialization of the module, which avoids having to re-initialize the module for each subsequent test. This can save an enormous amount of test time since the time required to initialize certain module embodiments may be very lengthy (e.g., booting a computer motherboard). Such “indexing” includes decoupling the plurality of probe needles from the respective plurality of electrical connection points of the first integrated circuit die, moving the probe chuck to position a second die beneath the probe needles, then contacting the plurality of probe needles to a respective plurality of electrical connection points of the second integrated circuit die. The second integrated circuit die is initialized to provide, together with the initialized module, the operable system-level environment, and then a system-level test of the second integrated circuit die is performed in the operable system-level environment. The controller 102 also interfaces with prober 104 to provide useful control signals for stepping through the various dies on the wafer, mapping failing dies, auto-loading new wafers, etc.

While not necessary, it is nevertheless helpful if such a test system is capable of running existing system-level test (SLT) diagnostics, and is designed to reduce such diagnostic test times, and also able to run structural testing, such as scan dump JTAG tests.

As used herein, a system-level environment or application is one utilizing a collaboration of multiple IC's. A product-level application may be considered as a subset of a system-level application. An example of a product-level application is off-the-shelf personal computer (PC) components that interact with the device-under-test (DUT) to make a sellable product.

As used herein, a motherboard implementation includes circuitry usually found on a computer motherboard, but not necessary having the usual form factor of an actual commercial motherboard product.

As used herein, “initiailizing” a module may include one or more of powering-up the module, configuring firmware on the module (i.e., on any device within the module), loading configuration registers or memory on the module, downloading operating parameters to the module, booting an operating system for the module, and any other action which is useful to place such module in a condition to provide a desired system-level environment.

As used herein, “initializing” an integrated circuit being tested (i.e., the “device under test” or DUT) may include one or more of powering-up the integrated circuit, configuring firmware on the integrated circuit, downloading operating parameters to the integrated circuit, loading configuration registers or memory within the integrated circuit, and any other action which is useful to place the integrated circuit in an operable condition in the system-level environment.

As used herein, a probe-load board may refer to a traditional probe card (e.g., including probe needles), and may refer to a load board having electrical components and characteristics frequently associated with a final test load board, to which a probe card is coupled, as described above, and may also refer to a combination of such a probe card mated with such a load board. Consequently, unless the context requires otherwise, a probe card and a probe-load board may be used interchangeably herein. Such a probe-load board may be implemented as one or more separable units, such as a probe card which is attachable to a load board, in which the probe needles are attached to the probe card (frequently for ease of repair and maintenance), and may also be implemented as a load board having, in effect, an integral probe card (including probe needles) as part of the load board.

As used herein, electrical connection points on an integrated circuit die include wire bond pads, C4 bumps, solder bumps, and any other electrical terminal for effectuating connection with such integrated circuit during testing or packaging.

As used herein, a semiconductor wafer is used in the broadest sense to include any kind of substrate for fabricating semiconductor devices, including without limitation bulk semiconductor wafers, epitaxial layer on bulk wafers, silicon-on-insulator (SOI) wafers, silicon-on-sapphire wafers, gallium arsenide wafers, and silicon carbide wafers.

As used herein, the word “exemplary” is intended to serve as one example embodiment and not to limit the application by construing the embodiment as preferred or advantageous over other embodiments. As used herein, a “set” includes at least one element or item, and does not necessary require a plurality. As used herein, “coupled” includes either directly coupled (i.e., no intervening devices, buses, or structures) or indirectly coupled (i.e., at least one intervening device, bus, or other structure). References in the claims to a numbered item, such as a “third” item, are for clarity, and do not necessarily imply that lower-numbered items of the same type are also included in the recited claim.

While circuits and physical structures have been generally presumed in describing some embodiments, it is well recognized that in modern semiconductor, computer, and mechanical design and fabrication, physical structures and circuits may be embodied in a computer-readable storage medium as data structures for use in subsequent design, simulation, test, or fabrication stages. For example, such data structures may encode a functional description of circuits or systems of circuits. The functionally descriptive data structures may be, e.g., encoded in a register transfer language (RTL), a hardware description language (HDL), in Verilog, or some other language used for design, simulation, and/or test. Data structures corresponding to embodiments described herein may also be encoded in, e.g., Graphic Database System II (GDSII) data, and functionally describe integrated circuit layout and/or information for photomask generation used to manufacture the integrated circuits. Other data structures, containing functionally descriptive aspects of embodiments described herein, may be used for one or more steps of the manufacturing process.

Computer-readable storage media include non-transitory, tangible computer readable media, e.g., a disk, tape, or other magnetic, optical, semiconductor, or electronic storage medium. In addition to computer-readable storage medium having encodings thereon of circuits, systems, and methods, the computer readable storage media may store instructions as well as data that can be used to implement embodiments described herein or portions thereof. The data structures may be utilized by software executing on one or more processors, firmware executing on hardware, or by a combination of software, firmware, and hardware, as part of the design, simulation, test, or fabrication stages.

The foregoing detailed description has described only a few of the many possible implementations. Moreover, the inventive aspects described herein are contemplated to be used alone as well as in various combinations. Consequently, this detailed description is intended by way of illustration, and not by way of limitations. Variations and modifications of the embodiments disclosed herein may be made based on the description set forth herein. It is only the claims, including all equivalents, in this or any application claiming priority to this application, that are intended to define the invention.

What is claimed is:

1. A method for testing integrated circuit die on a semiconductor wafer, said method comprising:
initializing a module comprising circuitry employed in a system-level circuit environment, to provide an operable system-level environment when coupled to an integrated circuit that is not present on the module;
contacting a plurality of probe needles to a respective plurality of electrical connection points of a first integrated circuit die on a semiconductor wafer, said plurality of probe needles being electrically coupled to respective connections on the module; then
initializing the first integrated circuit die to provide, together with the initialized module, the operable system-level environment; and then
performing a system-level test of the first integrated circuit die in the operable system-level environment.

2. The method as recited in claim 1 wherein said performing a system-level test comprises:
operating the first integrated circuit die in the system-level environment under at least one set of operating conditions; and
registering success or failure of the first integrated circuit die during such operation.

3. The method as recited in claim 1 further comprising:
decoupling the plurality of probe needles from the respective plurality of electrical connection points of the first integrated circuit die, while maintaining the initialization of the module; then
contacting the plurality of probe needles to a respective plurality of electrical connection points of a second integrated circuit die on the semiconductor wafer; then
initializing the second integrated circuit die to provide, together with the initialized module, the operable system-level environment; and then
performing a system-level test of the second integrated circuit die in the operable system-level environment.

4. The method as recited in claim 1 wherein:
the probe needles are part of a probe-load board for a wafer prober; and
the module is implemented, at least in part, external to the probe-load board, and is connected to the probe-load board by a cable.

5. The method as recited in claim 4 wherein:
the module is partially implemented on the probe-load board.

6. The method as recited in claim 1 wherein:
the probe needles are part of a probe-load board for a wafer prober; and
the module is implemented on the probe-load board.

7. The method as recited in claim 1 wherein:
the probe needles are part of a probe-load board for a wafer prober; and
the module is implemented, at least in part, within an automated test equipment (ATE) test head that is operably connected to the probe-load board.

8. The method as recited in claim 1 wherein:
the module comprises a motherboard implementation including an associated processor device;
said initializing the module comprises booting an operating system on the motherboard implementation; and
the first integrated circuit die includes a graphics processing unit (GPU).

9. The method as recited in claim 1 wherein:
the module comprises a motherboard implementation without an associated processor device; and
the first integrated circuit die comprises a processor device operable with the motherboard implementation.

10. The method as recited in claim 1 wherein the first integrated circuit die comprises a processor device.

11. The method as recited in claim 10 wherein the processor device includes at least one of a graphics processing unit (GPU), a central processing unit (CPU), and an accelerated processing unit (APU).

12. A test apparatus for testing an integrated circuit die on a semiconductor wafer, said test apparatus comprising:
a module comprising circuitry employed in a system-level circuit environment, said module operable to provide an operable system-level environment when initialized and coupled to an integrated circuit that is not present on the module;
a probe-load board operable with a wafer prober, said probe-load board comprising a plurality of probe needles operable to contact a respective plurality of electrical connection points of a first integrated circuit die on a semiconductor wafer, said plurality of probe needles being electrically coupled to respective connections on the module; and
a test controller operable to initialize the module and initialize the first integrated circuit die to provide, together with the initialized module, the operable system-level environment, and further operable to initiate and monitor a system-level test of the first integrated circuit die in the operable system-level environment.

13. The test apparatus as recited in claim 12 wherein said system-level test comprises:
operation of the first integrated circuit die in the system-level environment under at least one set of operating conditions; and
registration of success or failure of the first integrated circuit die during such operation.

14. The test apparatus as recited in claim 12 wherein the test controller is further operable to:
cause the wafer prober to decouple the plurality of probe needles from the respective plurality of electrical connection points of the first integrated circuit die, while maintaining the initialization of the module; then
cause the wafer prober to contact the plurality of probe needles to a respective plurality of electrical connection points of a second integrated circuit die on the semiconductor wafer; then
initialize the second integrated circuit die to provide, together with the initialized module, the operable system-level environment; and then
initiate and monitor a system-level test of the second integrated circuit die in the operable system-level environment.

15. The test apparatus as recited in claim 12 wherein:
the module is implemented, at least in part, external to the probe-load board, and is connected to the probe-load board by a cable.

16. The test apparatus as recited in claim 15 wherein:
the module is partially implemented on the probe-load board.

17. The test apparatus as recited in claim 12 wherein:
the module is implemented on the probe-load board.

18. The test apparatus as recited in claim 12 wherein:
the module is implemented, at least in part, within an automated test equipment (ATE) test head that is operably connected to the probe-load board.

19. The test apparatus as recited in claim 12 wherein:
the module comprises a motherboard implementation including an associated processor device; and
the module is initialized by booting an operating system on the motherboard implementation.

20. The test apparatus as recited in claim 12 wherein:
the first integrated circuit die comprises a processor device that includes at least one of a graphics processing unit (GPU), a central processing unit (CPU), and an accelerated processing unit (APU).
